(19) United States
(12) Patent Application Publication
(10) Pub. No.: US 2026/0231351 A1
(43) Pub. Date: Aug. 6, 2026

(54) ACTIVE COOLING INLET SCREEN

(71) Applicant: Dell Products L.P., Round Rock, TX (US)

(72) Inventors: Christopher A. Torres, San Marcos, TX (US); Deeder Aurongzeb, Austin, TX (US)

(21) Appl. No.: 19/046,001

(22) Filed: Feb. 5, 2025

(51) Int. Cl. H05K 7/20

(52) U.S. Cl. CPC H05K 7/20009

(57) ABSTRACT

An embodiment includes an information handling system. The information handling system includes a chassis comprising an active cooling inlet, the active cooling inlet comprising a plurality of air intake portions admitting airflow into the chassis. The apparatus includes a screen coupled to the chassis, the screen comprising a plurality of perforations allowing airflow through the screen and into the active cooling inlet, wherein each perforation in the plurality of perforations has an area smaller than an area of an air intake portion in the plurality of air intake portions.

### BACKGROUND

### Field of the Disclosure

The disclosure relates generally to an information handling system, and in particular, to an active cooling inlet screen.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY

Innovative aspects of the subject matter described in this specification may be embodied in an information handling system comprising: a chassis comprising an active cooling inlet, the active cooling inlet comprising a plurality of air intake portions admitting airflow into the chassis; and a screen coupled to the chassis, the screen comprising a plurality of perforations allowing airflow through the screen and into the active cooling inlet, wherein each perforation in the plurality of perforations has an area smaller than an area of an air intake portion in the plurality of air intake portions.

Other embodiments of these aspects include an information handling system comprising: a screen attachable to an active cooling inlet of a chassis, the active cooling inlet comprising a plurality of air intake portions admitting airflow into the chassis, the screen comprising a plurality of perforations allowing airflow through the screen and into the active cooling inlet, wherein each perforation in the plurality of perforations has an area smaller than an area of an air intake portion in the plurality of air intake portions.

Other embodiments of these aspects include a method providing elements of the apparatus.

Particular implementations of the subject matter described in this specification can be implemented so as to realize one or more of the following advantages. For example, providing an active cooling inlet screen for a computer system chassis enables a computer user to remove dust and other airflow-impeding particulates from an active cooling inlet screen without having to disassemble the chassis or otherwise risk damage to components within the chassis.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 depicts views of an example configuration for an active cooling inlet screen, in accordance with an illustrative embodiment.

FIG. 3 depicts additional views of an example configuration for an active cooling inlet screen, in accordance with an illustrative embodiment.

FIG. 4 depicts views of another example configuration for an active cooling inlet screen, in accordance with an illustrative embodiment.

FIG. 5 depicts views of another example configuration for an active cooling inlet screen, in accordance with an illustrative embodiment.

FIG. 6 depicts views of another example configuration for an active cooling inlet screen, in accordance with an illustrative embodiment.

FIG. 7 depicts views of another example configuration for an active cooling inlet screen, in accordance with an illustrative embodiment.

FIG. 8 depicts views of another example configuration for an active cooling inlet screen, in accordance with an illustrative embodiment.

FIG. 9 depicts a flowchart of an example process for an active cooling inlet screen. in accordance with an illustrative embodiment.

### DESCRIPTION OF PARTICULAR EMBODIMENT(S)

Information handling systems such as computer systems typically include an active cooling mechanism such as a fan. The fan moves airflow into a computer system chassis via one or more active cooling inlets, across computer system components such as a processor or memory, and out of the chassis, removing hot air from the chassis and thus cooling the interior of the computer system. However, changes in computer system utilization and environmental conditions in which computer systems are used have increased the likelihood of dust accumulation and other unwanted materials within computer systems. Dust accumulation and condensation in computer systems can decrease the effectiveness of the designed thermal system, shortening the lifecycle of key components (e.g., a fan, heat sink, or heat pipes) thus impacting the lifespan of the system as a whole.

Thus, the illustrative embodiments recognize that, to prevent dust and other contaminants from entering the chassis with the air, there is a need for an active cooling inlet screen disposed between an active cooling inlet and the outside. The screen should restrict the size of particles entering the system. The screen should have multiple mass production manufacturing options and a minimal impact when retrofit into existing system designs.

This disclosure discusses an apparatus and methods implementing an active cooling inlet screen of an information handling system. In particular, an embodiment includes an information handling system comprising a chassis comprising an active cooling inlet, the active cooling inlet comprising a plurality of air intake portions admitting airflow into the chassis; and a screen coupled to the chassis, the screen comprising a plurality of perforations allowing airflow through the screen and into the active cooling inlet, wherein each perforation in the plurality of perforations has an area smaller than an area of an air intake portion in the plurality of air intake portions.

An embodiment includes a chassis. In embodiments, the chassis includes an active cooling inlet. The active cooling inlet includes one or more air intake portions admitting airflow into the chassis. In some embodiments, the chassis at least partially encloses a computer system cooled using airflow admitted into the chassis via the active cooling inlet. In some embodiments, a fan moves airflow into a computer system chassis via one or more active cooling inlets, across computer system components such as a processor or memory, and out of the chassis, removing hot air from the chassis and thus cooling the interior of the computer system. In some embodiments, a bottom, side, or top portion of the chassis includes the active cooling inlet.

An embodiment includes a screen including a plurality of perforations allowing airflow through the screen and into the active cooling inlet. Each perforation has an area smaller than an area of an air intake portion of the active cooling inlet. In some embodiments, the perforations are formed by laser perforation, electroforming, chemical engraving or etching, or another presently available technique. In some embodiments, the screen is coupled to the chassis using a presently available adhesive applied to a border of the screen so as not to impede airflow through the screen. In other embodiments, the screen is coupled to the chassis using a magnetic closure, a snap closure, or another presently available technique that allows the screen to be decoupled from the chassis, cleaned or reoriented, and reinstalled.

In embodiments, the active cooling inlet includes a chamfer opening accepting airflow from a subset of the plurality of perforations. In some embodiments, the subset of perforations is oriented with respect to a portion of the active cooling inlet so as to control how much airflow enters the active cooling inlet. Such a configuration is useful if the perforations are larger than desired or if manufacturing perforations with a desired area is more expensive than desired. For example, a presently available stamping process is usable to generate a screen with larger than desired perforations.

In some embodiments, the screen is installable in two different orientations. In one orientation, screen perforations are aligned so as to provide a first amount of airflow into the chassis (e.g., a maximum possible airflow). In a second orientation, screen perforations are aligned so as to provide a second amount of airflow into the chassis, less than the first amount of airflow. In one embodiment, the second orientation is a 180-degree rotation from the first orientation, rotated about an axis perpendicular to the outside surface of the chassis and screen. In another embodiment, the second orientation is a 180-degree rotation from the first orientation, rotated about an axis parallel to the outside surface of the chassis (i.e., the outside and inside surfaces of the screen are swapped with each other). Other orientations, selected to provide a specified amount of airflow into the chassis, are also possible and contemplated within the scope of the illustrative embodiments.

In some embodiments, the perforations each have a substantially cylindrical cross-section. In other embodiments, the perforations each have a cross-section tapering from a first area at an external surface of the screen to a second area at an internal surface of the screen, and the first area is smaller than the second area. Other cross-section geometries are also possible and contemplated within the scope of the illustrative embodiments.

In some embodiments, each perforation has a cross-sectional diameter between approximately 0.5 millimeters and approximately 0.8 millimeters. In some embodiments, all of the perforations have approximately the same cross-sectional diameter. In other embodiments, the perforations are arranged in a gradient pattern from a first cross-sectional diameter (e.g., 0.5 millimeters) at one end of the screen to a second cross-sectional diameter larger than the first cross-sectional diameter (e.g., 0.8 millimeters) at the other end of the screen. In other embodiments, the perforations are arranged in a first group of perforations with a third cross-sectional diameter (e.g., 0.5 millimeters) and a second group of perforations with a fourth cross-sectional diameter (e.g., 0.8 millimeters). In some embodiments, these and other perforation arrangements are selected to provide specified amounts of airflow into specified portions of the chassis. Other perforation arrangements, providing other airflow configurations, are also possible and contemplated within the scope of the illustrative embodiments.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

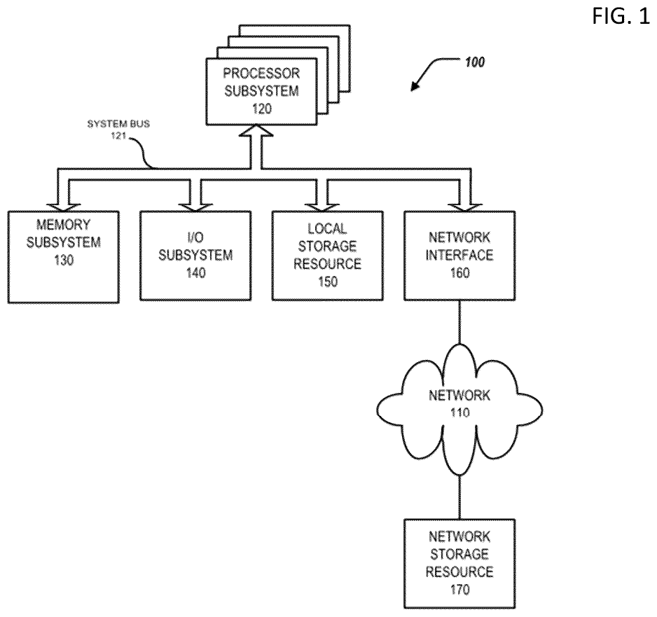

Particular embodiments are best understood by reference to FIGS. 1-5 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

The information handling system 100 can also include a software application. The software application can be included by the memory subsystem 130. The software application can include a computer-executable program (software). The software application can be executed by the processor subsystem 120.

The information handling system 100 can also include a second software application implementing embedded controller functionality. The second software application can be in communication with the processor subsystem 120 or included in the processor subsystem 120. In some examples, the second software application is included by an embedded controller (EC) of the information handling system 100. In some examples, the second software application is included by baseband management controller of the information handling system 100.

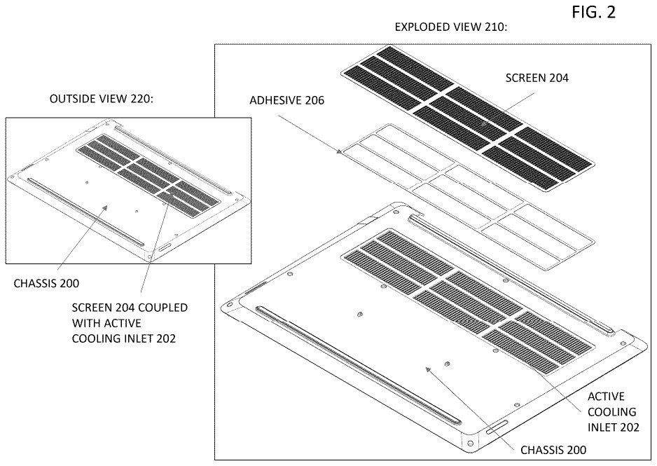

FIG. 2 depicts views of an example configuration for an active cooling inlet screen, in accordance with an illustrative embodiment. The active cooling inlet screen can be installed in information handling system 100 in FIG. 1.

Chassis 200 includes active cooling inlet 202. Active cooling inlet 202 includes one or more air intake portions admitting airflow into chassis 200. Chassis 200 at least partially encloses a computer system cooled using airflow admitted into chassis 200 via active cooling inlet 202. In some implementations, a fan (not shown) moves airflow into chassis 200 via active cooling inlet 202, across computer system components such as a processor or memory, and out of chassis 200, removing hot air from chassis 200 and thus cooling the interior of the computer system. As depicted in FIG. 2, a bottom surface of chassis 200 includes active cooling inlet 202. In other implementations another surface of chassis 200 includes active cooling inlet 202.

Screen 204 includes a plurality of perforations allowing airflow through screen 204 and into active cooling inlet 202. Each perforation has an area smaller than an area of an air intake portion of active cooling inlet 204. In some implementations, the perforations are formed by laser perforation, electroforming, chemical engraving or etching, or another presently available technique. In some implementations, screen 204 is coupled to chassis 200 using adhesive 206 applied to a border of screen 204 so as not to impede airflow through the screen. In other implementations (not shown), screen 204 is coupled to chassis 200 using a magnetic closure, a snap closure, or another presently available technique that allows the screen to be decoupled from the chassis, cleaned or reoriented, and reinstalled.

Exploded view 210 depicts chassis 200, active cooling inlet 204, screen 204, and adhesive 206 as individual parts. Outside view 220 depicts an outside surface of chassis 200 (e.g., a bottom surface) including screen 204 coupled with active cooling inlet 202.

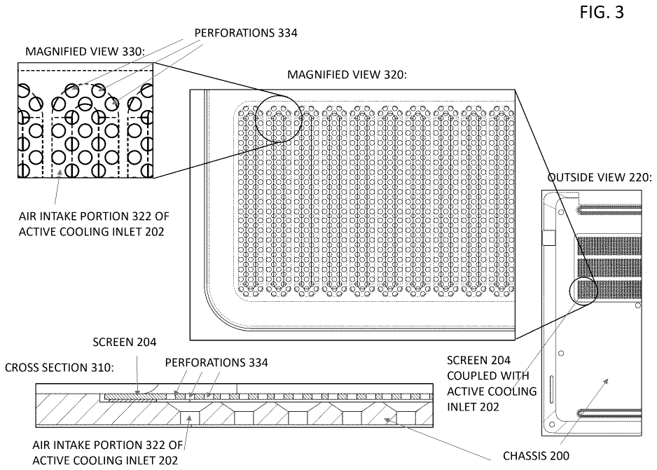

FIG. 3 depicts additional views of an example configuration for an active cooling inlet screen, in accordance with an illustrative embodiment. Chassis 200, active cooling inlet 202, screen 204, and outside view 220 are the same as chassis 200, active cooling inlet 202, screen 204, and outside view 220 in FIG. 2.

Outside view 220 depicts a portion of chassis 200 and screen 204 coupled with active cooling inlet 202. Magnified view 320 depicts a magnified view of a portion of outside view 220, and magnified view 330 depicts a further magnified view of a portion of magnified view 320. In particular, magnified view 330 depicts a further magnified view of air intake portion 322 of active cooling inlet 202. Air intake portion 322 is a chamfer opening accepting airflow from a subset of the perforations in screen 204, including for example perforations 334. The perforations, including perforations 334, are oriented with respect to air intake portion 322 so as to control how much airflow enters active cooling inlet 202. Such a configuration is useful if the perforations are larger than desired or if manufacturing perforations with a desired area is more expensive than desired. For example, a presently available stamping process is usable to generate a screen with larger than desired perforations.

Cross section 310 depicts a cross section of screen 204 (including perforations 334) coupled to chassis 200 (including air intake portion 332 of active cooling inlet 202).

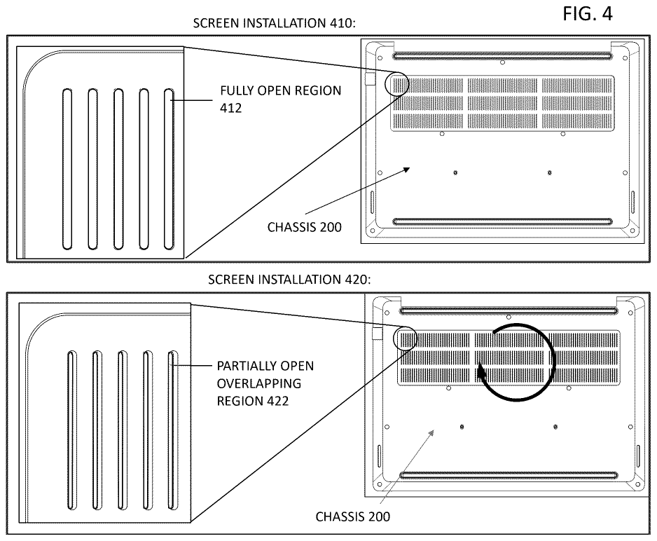

FIG. 4 depicts views of another example configuration for an active cooling inlet screen, in accordance with an illustrative embodiment. Chassis 200 is the same as chassis 200 in FIG. 2.

As depicted in screen installation 410, screen perforations are aligned so as to provide a first amount of airflow into the chassis (e.g., fully open region 412). As depicted in screen installation 420, screen perforations are aligned so as to provide a second amount of airflow into the chassis, less than the first amount of airflow (e.g., partially open overlapping region 422). In one implementation, the second orientation is a 180-degree rotation from the first orientation, rotated (e.g., clockwise) about an axis perpendicular to the outside surface of the chassis and screen. Other orientations, selected to provide a specified amount of airflow into the chassis, are also possible.

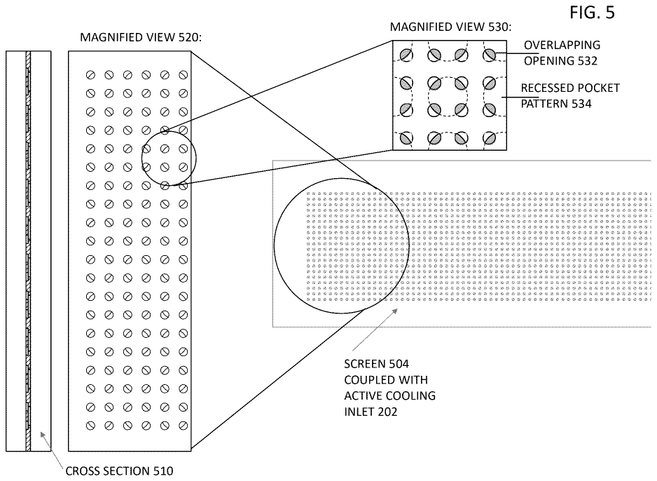

FIG. 5 depicts views of another example configuration for an active cooling inlet screen, in accordance with an illustrative embodiment. Active cooling inlet 202 is the same as active cooling inlet 202 in FIG. 2.

Magnified view 520 depicts a magnified view of a portion of screen 504 coupled to active cooling inlet 202. Magnified view 530 depicts a further magnification of magnified view 520, including overlapping opening 532, a result of a perforation overlapping recessed pocket pattern 534 of active cooling inlet 202. Cross section 510 depicts a cross section of screen 504 including perforations. As depicted in FIG. 5, all of the perforations have approximately the same cross-sectional diameter.

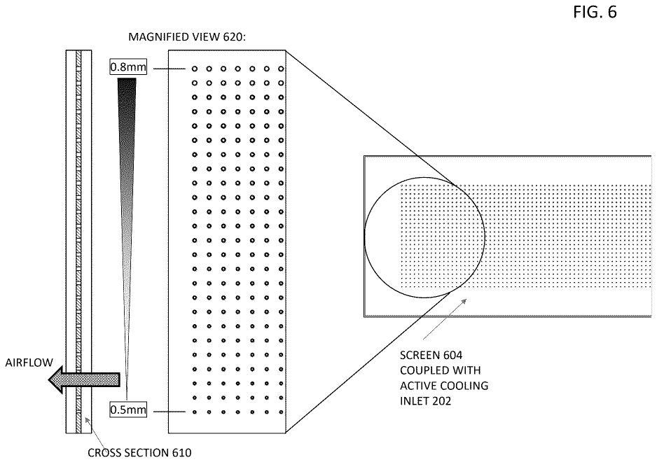

FIG. 6 depicts views of another example configuration for an active cooling inlet screen, in accordance with an illustrative embodiment. Active cooling inlet 202 is the same as active cooling inlet 202 in FIG. 2.

Magnified view 620 depicts a magnified view of a portion of screen 604 coupled to active cooling inlet 202. As depicted, the perforations are arranged in a gradient pattern from a first cross-sectional diameter (e.g., 0.5 millimeters) at one end of screen 604 to a second cross-sectional diameter larger than the first cross-sectional diameter (e.g., 0.8 millimeters) at the other end of screen 604. Cross section 610 depicts a cross section of screen 604 including perforations. Air flows from right to left across cross section 610 and into active cooling inlet 202. As depicted in cross section 610, the perforations each have a substantially cylindrical cross-section.

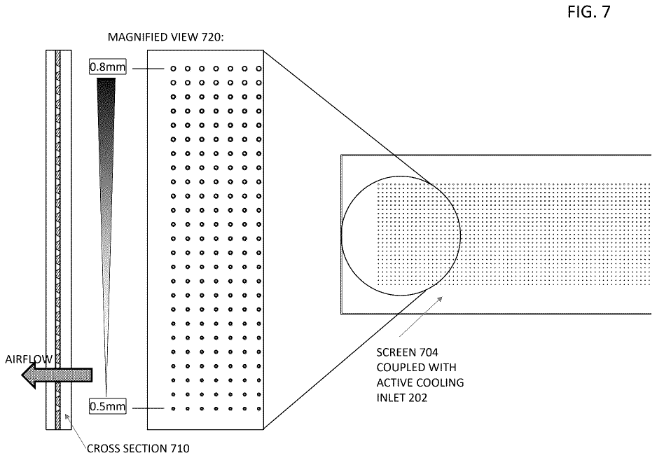

FIG. 7 depicts views of another example configuration for an active cooling inlet screen, in accordance with an illustrative embodiment. Active cooling inlet 202 is the same as active cooling inlet 202 in FIG. 2.

Magnified view 720 depicts a magnified view of a portion of screen 704 coupled to active cooling inlet 202. As depicted, the perforations are arranged in a gradient pattern from a first cross-sectional diameter (e.g., 0.5 millimeters) at one end of screen 704 to a second cross-sectional diameter larger than the first cross-sectional diameter (e.g., 0.8 millimeters) at the other end of screen 704. Cross section 710 depicts a cross section of screen 704 including perforations. Air flows from right to left across cross section 710 and into active cooling inlet 202. As depicted in cross section 710, the perforations each have a cross-section tapering from a first area at an external surface of the screen (here, the right side of cross section 710) to a second area at an internal surface of the screen (here, the left side of cross section 710), and the first area is smaller than the second area.

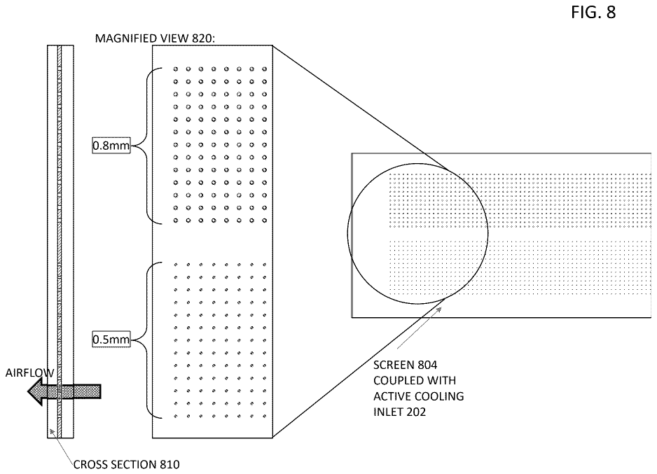

FIG. 8 depicts views of another example configuration for an active cooling inlet screen, in accordance with an illustrative embodiment. Active cooling inlet 202 is the same as active cooling inlet 202 in FIG. 2.

Magnified view 820 depicts a magnified view of a portion of screen 804 coupled to active cooling inlet 202. As depicted, the perforations are arranged in a first group of perforations with a third cross-sectional diameter (e.g., 0.5 millimeters) and a second group of perforations with a fourth cross-sectional diameter (e.g., 0.8 millimeters). Cross section 810 depicts a cross section of screen 804 including perforations. Air flows from right to left across cross section 810 and into active cooling inlet 202. As depicted in cross section 810, the perforations each have a substantially cylindrical cross-section.

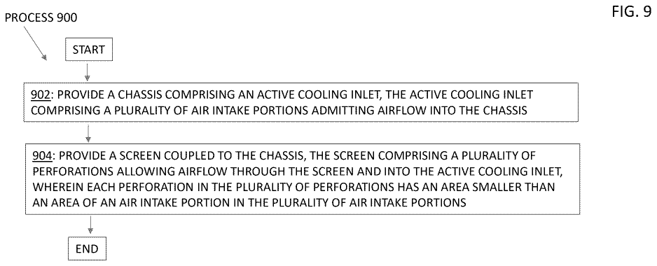

FIG. 9 depicts a flowchart of an example process for an active cooling inlet screen. in accordance with an illustrative embodiment.

In block 902 of process 900, the process provides a chassis comprising an active cooling inlet, the active cooling inlet comprising a plurality of air intake portions admitting airflow into the chassis. In block 904, the process provides a screen coupled to the chassis, the screen comprising a plurality of perforations allowing airflow through the screen and into the active cooling inlet, wherein each perforation in the plurality of perforations has an area smaller than an area of an air intake portion in the plurality of air intake portions. Then the process ends.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. An information handling system comprising:
a chassis comprising an active cooling inlet, the active cooling inlet comprising a plurality of air intake portions admitting airflow into the chassis; and
a screen coupled to the chassis, the screen comprising a plurality of perforations allowing airflow through the screen and into the active cooling inlet, wherein each perforation in the plurality of perforations has an area smaller than an area of an air intake portion in the plurality of air intake portions.

2. The information handling system of claim 1, wherein the screen is coupled to the chassis using an adhesive.

3. The information handling system of claim 1, wherein the screen is coupled to the chassis using a magnetic closure.

4. The information handling system of claim 1, wherein the active cooling inlet comprises a chamfer opening accepting airflow from a subset of the plurality of perforations.

5. The information handling system of claim 1, wherein the screen is coupled to the chassis in a first orientation, the first orientation providing a first amount of airflow into the chassis.

6. The information handling system of claim 5, wherein the screen is coupled to the chassis in a second orientation, the second orientation providing a second amount of airflow into the chassis, wherein the second amount of airflow is less than the first amount of airflow.

7. The information handling system of claim 6, wherein the second orientation is a 180-degree rotation from the first orientation.

8. The information handling system of claim 6, wherein the screen is coupled to the chassis in a third orientation, the third orientation selected to provide a specified amount of airflow into the chassis.

9. The information handling system of claim 1, wherein each perforation has a cross-sectional diameter between approximately 0.5 millimeters and approximately 0.8 millimeters.

10. The information handling system of claim 1, wherein each perforation in the plurality of perforations has a substantially cylindrical cross-section.

11. The information handling system of claim 10, wherein the plurality of perforations is arranged in a gradient pattern from a first cross-sectional diameter to a second cross-sectional diameter larger than the first cross-sectional diameter.

12. The information handling system of claim 11, wherein the first cross-sectional diameter is equal to 0.5 millimeters and the second cross-sectional diameter is equal to 0.8 millimeters.

13. The information handling system of claim 10, wherein the plurality of perforations is arranged in a first group of perforations with a third cross-sectional diameter and a second group of perforations with a fourth cross-sectional diameter.

14. The information handling system of claim 1, wherein each perforation in the plurality of perforations has a cross-section tapering from a first area at an external surface of the screen to a second area at an internal surface of the screen, wherein the first area is smaller than the second area.

15. An information handling system comprising:
a screen attachable to an active cooling inlet of a chassis, the active cooling inlet comprising a plurality of air intake portions admitting airflow into the chassis, the screen comprising a plurality of perforations allowing airflow through the screen and into the active cooling inlet, wherein each perforation in the plurality of perforations has an area smaller than an area of an air intake portion in the plurality of air intake portions.

16. The information handling system of claim 15, wherein the screen is coupled to the chassis using an adhesive.

17. The information handling system of claim 15, wherein the screen is coupled to the chassis using a magnetic closure.

18. The information handling system of claim 15, wherein the screen is coupled to the chassis in a first orientation, the first orientation providing a first amount of airflow into the chassis.

19. The information handling system of claim 18, wherein the screen is coupled to the chassis in a second orientation, the second orientation providing a second amount of airflow into the chassis, wherein the second amount of airflow is less than the first amount of airflow.

20. A method, comprising:
providing a chassis comprising an active cooling inlet, the active cooling inlet comprising a plurality of air intake portions admitting airflow into the chassis; and
a screen coupled to the chassis, the screen comprising a plurality of perforations allowing airflow through the screen and into the active cooling inlet, wherein each perforation in the plurality of perforations has an area smaller than an area of an air intake portion in the plurality of air intake portions.
